(19) United States
(12) Patent Application Publication
(10) Pub. No.: US 2025/0132729 A1
(43) Pub. Date: Apr. 24, 2025

(54) OUTPUT CURRENT-DEPENDENT VOLTAGE REGULATOR OUTPUT STAGE RECONFIGURATION

(71) Applicant: CIRRUS LOGIC INTERNATIONAL SEMICONDUCTOR LTD., Edinburgh (GB)

(72) Inventors: Rupesh Khare, Newbury (GB); Ambreesh Bhattad, Fountain Hills, AZ (US); Jithender Tirunahari, Chandler, AZ (US)

(21) Appl. No.: 18/492,853

(22) Filed: Oct. 24, 2023

(51) Int. Cl. H03F 1/02; H03F 3/04

(52) U.S. Cl. CPC H03F 1/0211; H03F 3/04

(57) ABSTRACT

An amplifier circuit employing an output stage current mirror has improved power efficiency and stability. The amplifier circuit includes one or more amplifier stages connected in cascade. The one or more amplifier stages receive an analog input signal and generate a drive signal. The current mirror output stage includes an output device and a diode-connected mirror device. A gate of the output device is coupled to a gate of the mirror device, and the mirror device is coupled to an output of the one or more amplifier stages to receive the drive signal. The current mirror output stage provides an adjustable ratio by activation of one more additional devices that are selectively coupled to a mirror arm and an output arm of the current mirror output stage, decreasing the pre-driver power dissipation for high current levels, and decreasing the output capacitance at lower current levels, improving stability.

### BACKGROUND

### 1. Field of Disclosure

The field of representative embodiments of this disclosure relates to voltage regulator circuits and amplifiers for implementing voltage regulators, and in particular to an amplifier having an output stage that is reconfigured based on output current.

### 2. Background

Voltage regulators, and other amplifier-based power output circuits, typically use multiple amplification stages to provide a high gain signal path for error cancellation via feedback. The high open-loop gain employed in the amplifier circuits is needed for obtaining a necessary power supply rejection-ratio (PSRR) and high accuracy in obtaining a required output voltage and/or current. Such multi-stage circuits are typically difficult to stabilize over a full range of operating conditions, since each stage contributes a pole to the overall open-loop response, which may result in oscillation and improper transient behavior when the feedback is applied. In particular, when a power output circuit is under low load conditions, the power output device, which is generally much larger than the devices in the earlier stages, has an output impedance that increases with a decrease in load current. The decreased impedance can result in the frequency of the pole of the output stage coming within the closed-loop bandwidth of the amplifier-based power output circuit, causing unstable operation.

A typical solution to the instability problem is to provide a guaranteed minimum load current, typically by incorporating a parallel resistive load, or by reducing the size of the power output device, which is undesirable due to increase losses in the final power output stage. In a current-mirror driven design, the change in the output power device size represents a reduction in ratio of the output current mirror, which further reduces efficiency due to power dissipation in the pre-driver mirror device(s).

Therefore, it would be advantageous to provide an amplifier circuit and method of operation that provide improved stability without compromising the size of power output devices, and in particular, in current-mirror output stages, without compromising the ratio of the output current-mirror.

### SUMMARY

Improved stability in an amplifier-based power output stage is accomplished in amplifier circuits and their methods of operation.

The amplifier circuits include one or more amplifier stages connected in cascade. The one or more amplifier stages receive an analog input signal and generate a drive signal. The amplifier circuits also include a current mirror output stage, which includes an output device and a diode-connected mirror device. A gate of the output device is coupled to a gate of the mirror device, and the mirror device is coupled to an output of the one or more amplifier stages to receive the drive signal. The current mirror output stage provides an adjustable ratio by activation of one more additional devices that are selectively coupled to a mirror arm and an output arm of the current mirror output stage.

The summary above is provided for brief explanation and does not restrict the scope of the claims. The description below sets forth example embodiments according to this disclosure. Further embodiments and implementations will be apparent to those having ordinary skill in the art. Persons having ordinary skill in the art will recognize that various equivalent techniques may be applied in lieu of, or in conjunction with, the embodiments discussed below, and all such equivalents are encompassed by the present disclosure.

### BRIEF DESCRIPTION OF THE DRAWINGS

FIG. 1 is a block diagram illustrating an example system 10 in accordance with an embodiment of the disclosure.

FIG. 2 is a block diagram illustrating details of an example voltage regulator circuit 20, which may be used to implement LDO 20 in example system 10 of FIG. 1, in accordance with an embodiment of the disclosure.

FIG. 3 is a schematic diagram illustrating an example voltage regulator circuit 20A, which may be used to implement voltage regulator 20 of FIG. 2, in accordance with an embodiment of the disclosure.

FIG. 4 is a schematic diagram illustrating another example voltage regulator circuit 20B, which may be used to implement voltage regulator 20 of FIG. 2, in accordance with another embodiment of the disclosure.

FIG. 5 is a schematic diagram illustrating another example voltage regulator circuit 20C, which may be used to implement voltage regulator 20 of FIG. 2, in accordance with another embodiment of the disclosure.

FIG. 6 is a schematic diagram illustrating a reference circuit 40 that may be used to generate reference voltage V_{casp} in voltage regulator circuit 20C of FIG. 5, in accordance with an embodiment of the disclosure.

FIG. 7 is an example graph 50 illustrating operation of example voltage regulator circuit 20C of FIG. 5, in accordance with an embodiment of the disclosure.

FIG. 8 is a schematic diagram illustrating another example voltage regulator circuit 20D, which may be used to implement voltage regulator 20 of FIG. 2, in accordance with another embodiment of the disclosure.

### DETAILED DESCRIPTION OF ILLUSTRATIVE EMBODIMENT

The present disclosure encompasses circuits and integrated circuits that include amplifier circuits having improved power efficiency and stability. The amplifier circuits include one or more amplifier stages connected in cascade. The one or more amplifier stages receive an analog input signal and generate a drive signal. The amplifier circuits also include a current mirror output stage, which includes an output device and a diode-connected mirror device. A gate of the output device may be coupled to a gate of the mirror device, and the mirror device may be coupled to an output of the one or more amplifier stages to receive the drive signal. The current mirror has an adjustable ratio, so that at higher output current levels, a high level of the ratio of output current to pre-drive current is maintained for efficiency, while at lower current output levels, a lower ratio is provided to maintain stability, by reducing the capacitance at the output of the amplifier. The current mirror output stage provides the adjustable ratio by activation of one more additional devices that are selectively coupled to a mirror arm and an output arm of the current mirror output stage.

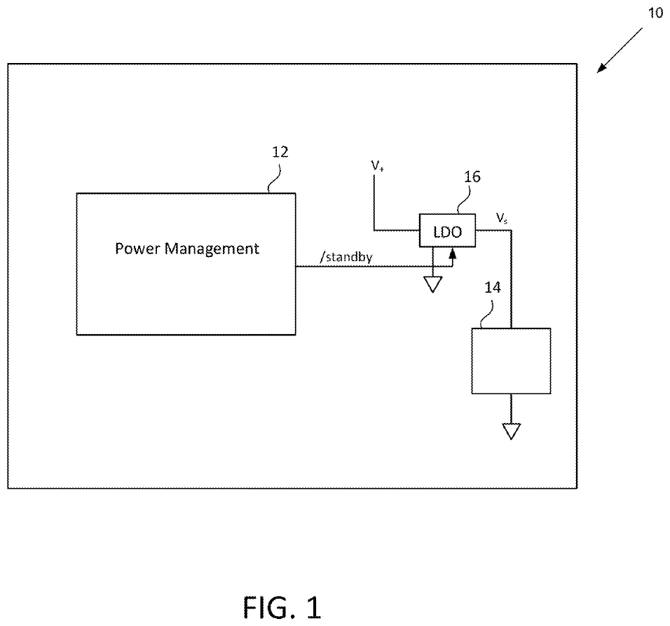

Referring now to FIG. 1, a block diagram illustrating an example system 10 is shown, in accordance with an embodiment of the disclosure. Example system 10 may form an integrated circuit (IC), form a portion of an IC, or may be implemented with separate ICs/devices. Example system 10 is only one example of a type of system in which voltage regulator circuits according to the various embodiments of the disclosure may be employed. A power management unit (PMU) 12 controls an operating state of functional units 14 within example system 10. A low-dropout voltage regulator (LDO) 16 provides operating power to functional units 14, and is responsive to a control signal/standby provided from PMU 12 to enter a standby state and remove operating power from functional units 14, for example, by shutting down the power output that supplies a supply voltage V_{S} to functional units 14.

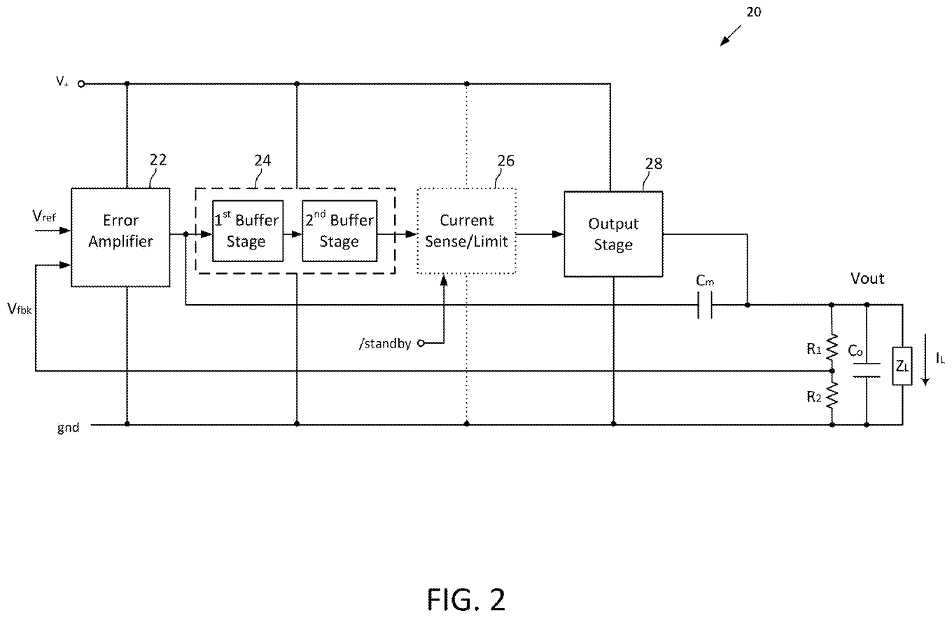

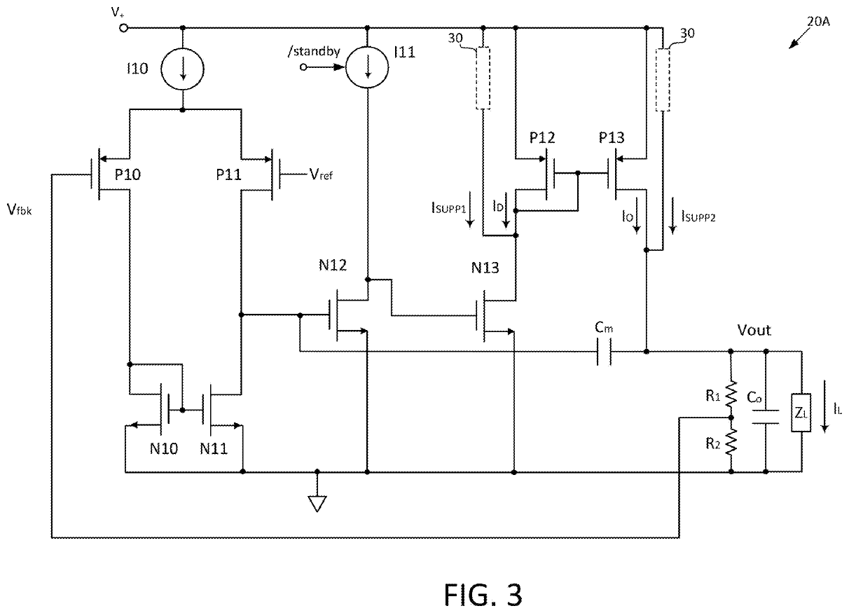

Referring now to FIG. 2, a block diagram illustrating details of an example voltage regulator circuit 20, which may be used to implement LDO 16 in example system 10 of FIG. 1, is shown, in accordance with an embodiment of the disclosure. Example voltage regulator circuit 20 is a linear regulator formed by a cascade of amplifier stages, operated by a power supply voltage V₊. A first stage implements an error amplifier 22 that generates an output by comparing a reference voltage V_{ref} with a feedback signal derived from an output voltage Vₒᵤₜ of example voltage regulator circuit 20 by a resistive divider composed of resistors R1 and R2. The output of error amplifier 22 is received by an intermediate amplifier stage 24 composed of two buffer amplifier stages. The output of intermediate amplifier stage 24 is optionally provided to a current level sense/limit block 26 that may determine an output current level provided by output stage 28, and which may prevent the input of output stage 28 being set to a level that exceeds a current limit value. In particular, with reference to the specific amplifier schemes described below with reference to FIGS. 3-5, the connection between intermediate amplifier stage 24 and output stage 28 may be provided by a current mirror that multiplies a signal current level provided to the diode-connected input device of the current mirror by intermediate amplifier stage 24.

An output stage reconfiguration scheme that will be described in further detail below with reference to FIGS. 3-5, is implemented by output stage 28, which switches at least one device between the input arm and the output arm of the current mirror, so that at low output current levels, the movement of the pole of output stage is prevented from entering the bandwidth of the overall amplifier forming example voltage regulator circuit 20. Control signal/standby may be applied to disable example voltage regulator circuit 20 in various ways, e.g., to cause the signal path to turn off output stage 28, but in the depicted example, control signal/standby is applied to current level sense/limit block 26 to disable output stage 28. Output stage 28 is formed by an output device of the current mirror that is sized to produce an output current level that is greater than the input current provided through the diode-connected device by a factor of, e.g., 10×-100×, so that current sense/limit block 26 may be informed of an output current level by the current level provided through the diode-connected device of the current mirror. A capacitor Co represents a total capacitance at the output of example voltage regulator circuit 20, which may be a supplemental circuit capacitor, if required for stability. An impedance Z_{L} represents a load to which example voltage regulator circuit 20 delivers a load current I_{L}. A capacitor Cₘ is a degeneration/negative feedback capacitor provided to compensate example voltage regulator circuit 20 across nominal operating conditions.

Referring now to FIG. 3, a schematic diagram illustrating an example voltage regulator circuit 20A, which may be used to implement voltage regulator circuit 20 of FIG. 2, is shown, in accordance with an embodiment of the disclosure. A pair of transistors P10, P11 provide a differential input stage to implement error amplifier 22 of FIG. 2, and a pair of transistors N10, N11 are connected to form a current mirror to bias the input stage, which splits a power supply current provided by current source 110 from power supply voltage V+. Transistors N12 and N13 implement the buffer amplifiers of intermediate amplifier stage 24 of FIG. 2, and are supplied their respective operating currents by current source I11 and by diode-connected transistor P12 that forms the input arm of a current mirror formed by transistors P12 and P13. As mentioned above, control signal/standby may be applied to disable example voltage regulator circuit 20 in various ways, e.g., to cause the signal path to turn off transistor P13, but in the depicted example, control signal/standby is applied to disable current source 12, when control signal/standby is asserted, disabling transistor N13 and transistors P12 and P13 of output stage 28 in example voltage regulator circuit 20 of FIG. 2, thereby. The output of the amplifier stages formed by transistors N12 and N13 is a current I_{O} conducted by transistor N13, which is mirrored by the current mirror formed by transistors P12 and P13, in which transistor P12 provides the diode-connected input arm, and transistor P13 is the power output device that supplies output voltage Vₒᵤₜ and load current I_{L} to load Z_{L}. Transistor P13 may be, for example, 10-100 times the size of transistor P12, in order to provide high efficiency by not wasting power supply current conducted through pre-driver/buffer device N13 and diode-connected mirror input transistor P12, which would otherwise be wasted in heat dissipated in voltage regulator circuit 20A. A current I_{D} conducted by transistor P12 is sunk by the last transistor N13 implementing the output of intermediate amplifier stage 24 of FIG. 2. Current I_{D} is multiplied by the current mirror ratio to obtain output current I_{O}, which is conducted through transistor P13.

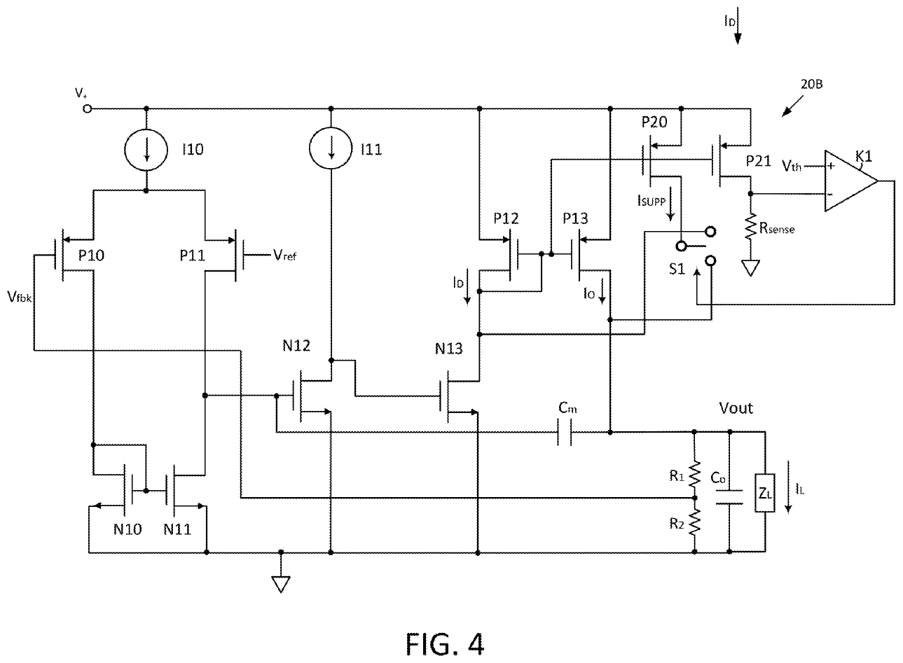

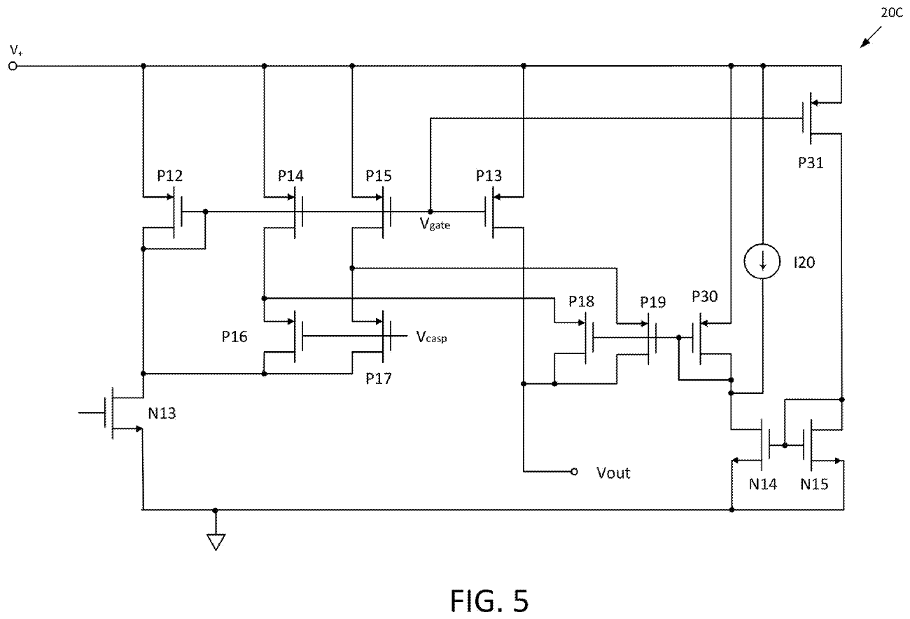

When load current I_{L} decreases, the pole due to transistor P13 decreases in frequency, which may cause voltage regulator circuit 20A to become unstable, if the pole enters the bandwidth of the amplifier implementing voltage regulator circuit 20A, and as mentioned above, one or more additional devices 30 are provided to reconfigure the ratio of the current mirror formed by transistors P12 and P13, along with the one or more additional devices 30. For example, the one or more additional devices may be a single P-channel FET that is selectively coupled to either the input arm or the output arm of the current mirror. By providing the one or more additional devices 30, which may for example, have half of the area required for transistor P13 to meet output impedance requirements, when an additional device coupled in parallel with transistor P13 is disabled, or reconfigured to be in parallel with transistor P12, the pole frequency is doubled over the pole frequency when the additional device is enabled or configured to be in parallel with transistor P13. Examples of types of output stage reconfiguration are described below with reference to FIGS. 4 and 5. The one or more additional devices 30 provide one or both of supplemental currents I_{SUPP1} and I_{SUPP2}, according to various selection schemes as will be illustrated in detail below. When supplemental current I_{SUPP1} is present, the current mirror ratio is effectively reduced, since the input current conducted through transistor N13 will be divided between the channel of transistor P12 and the one or more additional devices 30 conducting supplemental current I_{SUPP1}, which causes a reduction in the gate-source voltage of transistor P12, and which controls the output current mirror, i.e., the input current conducted by transistor N13 under these conditions is I_{D}+I_{SUPP1}. Similarly, when supplemental current I_{SUPP2} is present, the current mirror ratio is effectively increased, since the output current I_{O} provided by transistor P13 is supplemented by supplemental current I_{SUPP2}, i.e., for a given value of gate-source voltage of transistor P12, supplemental current I_{SUPP2} conducted by the one or more additional devices 30 will be added to output current I_{O} to increase load current I_{L}.

Referring now to FIG. 4, a schematic diagram illustrating another example voltage regulator circuit 20B, which may be used to implement voltage regulator circuit 20 of FIG. 2, is shown, in accordance with another embodiment of the disclosure. Example voltage regulator circuit 20B of FIG. 4 is similar to example voltage regulator circuit 20A of FIG. 3, so only differences between them will be described below. In example voltage regulator circuit 20B, an additional P-channel transistor P20 is selectively coupled in parallel with either transistor P12 or transistor P13, depending on the level of output current I_{L}. A mirror transistor P21, having a gate coupled to the gates of transistor P12 and transistor P13, conducts a sense current that is a mirrored version of the current passing through the channel of P12, which corresponds to a level of output current I_{L}. The current conducted through mirror transistor P21 is also conducted through a sense resistor Rₛₑₙₛₑ to generate a voltage that is compared to a threshold voltage Vₜₕ by a comparator K1. When output current I_{L} is greater than a threshold current level, the voltage across sense resistor Rₛₑₙₛₑ will be greater than threshold voltage Vₜₕ, causing switch S1 to couple transistor P20 in parallel with transistor P13. The output transistor size dictated by the required maximum value of output current I_{L} may be implemented as the size of the areas of transistor P13 and transistor P20. When output current I_{L} is less than or equal to the threshold current level, the voltage across sense resistor R_{S} will be less than or equal to threshold voltage Vₜₕ, causing switch S1 to couple transistor P20 in parallel with transistor P12. Under lower load current conditions, the current mirror ratio of the current mirror formed by transistors P12, P13 and P30 changes from a higher ratio, to a lower ratio, for example, from 100 to 50, because supplemental current I_{SUPP} is directed to transistor N13 and the gate and source of transistor P20 are coupled to the gate and source of transistor P12, respectively, which causes the gate-source voltage to be reduced for a given value of input current, which is I_{SUPP}+I_{D}. The output arm of the current mirror, and thus the pole due to the output stage then changes according to the change in ratio, since the effective area of the output device changes from that of transistor P13 combined with transistor P20 to that of transistor P13 alone.

Referring now to FIG. 5, a schematic diagram illustrating another example voltage regulator circuit 20C, which may be used to implement voltage regulator circuit 20 of FIG. 2, in accordance with another embodiment of the disclosure. Example voltage regulator circuit 20C of FIG. 5 is similar to example voltage regulator circuit 20B of FIG. 4, so only differences between them will be described below. In example voltage regulator circuit 20C, an additional P-channel FET P14 is selectively coupled in parallel with either transistor P12 or transistor P13, or both, depending on the level of output current I_{L}. Transistor P16 and transistor P18 act as switches that couple transistor P14 in parallel with either transistor P12, or transistor P13, respectively, although the switching action is more gradual than an ordinary switch, so that a smooth transition in current mirror ratio is achieved. A mirror transistor P31 conducts a sense current that is a mirrored version of the level of current through transistor P12, which also is mirrored by a current mirror formed by N-channel transistor N14 and N15, which is again mirrored by a current mirror formed by P-channel transistors P30, P18 and P19. As the level of current through transistor P12 increases, thus increasing the output current provided at terminal voltage Vₒᵤₜ, transistor N14 conducts more current, raising the level of current conducted through the current mirror formed by P-channel transistors P30, P18 and P19. Increased conduction by transistor P18 and transistor P19 raises the portion of current that is conducted by transistors P14 and P15 through transistor P18 and transistor P19, “stealing” current from the currents conducted through transistor P16 and P17, respectively that otherwise share the input current conducted by transistor N13. The effect is that for higher output current levels, the current conducted through transistors P14 and P15 is added to the current provided by output device P13, while for lower output current levels, the current conducted through transistors P14 and P15 is added to the current conducted by transistor N13, changing the current mirror ratio between the input arm and the output arm of the overall output stage current mirror. An additional current source 120 introduces a hysteresis current conducted by the current mirror formed by P-channel transistors P30, P18 and P19, so that there is no output current level for which the selection of the conduction pathways will toggle. A bias voltage V_{casp} provides for adjustment of the output current threshold level, and depending on the sizing of the devices in the current mirror, a more gradual or more abrupt shift of the current conducted through transistors P14 and P15 to either the input arm or the output arm of the overall output current mirror may be implemented.

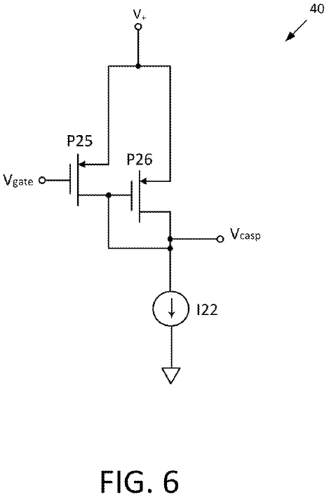

Referring now to FIG. 6, a schematic diagram is shown illustrating a reference circuit 40 that may be used to generate reference voltage V_{casp} in voltage regulator circuit 20C of FIG. 5, in accordance with an embodiment of the disclosure. A diode-connected transistor P26 provides a buffer having an output one threshold voltage level voltage drop from the voltage level at the gate terminal of a transistor P25, which is gate voltage V_{gate} of the overall output current mirror in voltage regulator circuit 20C of FIG. 5. Transistor P26 has a current level set by a current source 22 for operation to generate reference voltage V_{casp} as an output two threshold voltages below gate voltage V_{gate}, which sets reference voltage V_{casp} to turn on transistors P16 and P17 that conduct supplemental current in the input arm of the overall output current mirror in voltage regulator circuit 20C of FIG. 5.

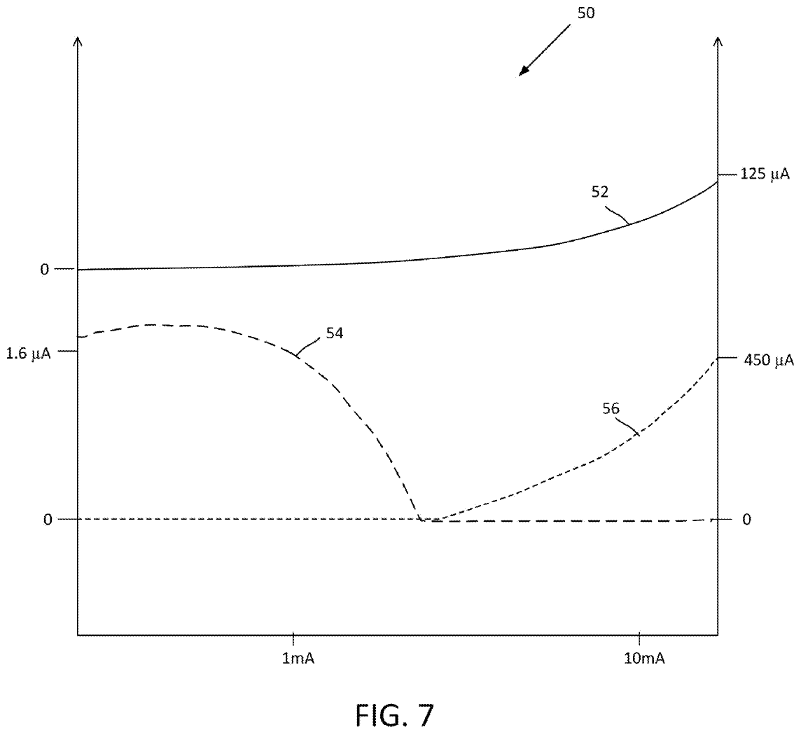

Referring now to FIG. 7, an example graph 50, illustrating operation of example voltage regulator circuit 20C of FIG. 5 is shown, in accordance with an embodiment of the disclosure. Graph 50 shows operation over a range of load current I_{L} from a few microamperes to approximately 10 mA. Curve 52 corresponds to the input current, which is the current conducted by diode device P12, along with any conduction through transistors P16 and P17. Curve 54 illustrates, with a scale on the left side of graph 50, the current conducted by the “switch” formed by transistors P16 and P17, while curve 56, with a scale on the right side of graph 50, illustrates the current conducted by the “switch” formed by transistors P18 and P19, which is two orders of magnitude greater than the current illustrated by curve 54, due to the designed current mirror ratio. As shown, the current conducted through transistors P16 and P17 is at a maximum for the lowest level of load current I_{L} and decreases until a load current of approximately 3 mA is reached, at which point, the current conducted through transistors P16 and P17 has decreased to zero and the current conducted by the “switch” formed by transistors P18 and P19 begins increasing, increasing the current mirror ratio to conserve power in the input arm of the current mirror.

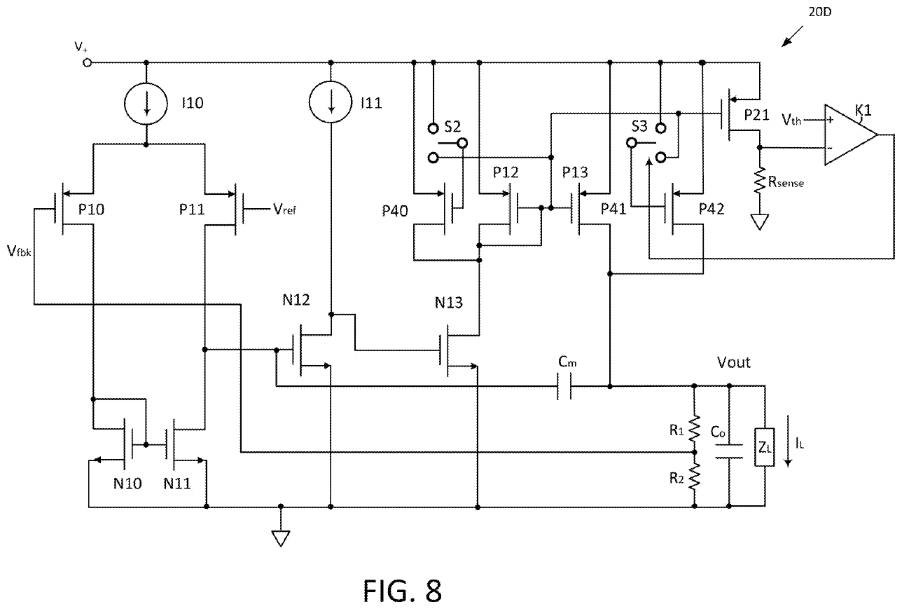

Referring now to FIG. 8, a schematic diagram illustrating another example voltage regulator circuit 20D, which may be used to implement voltage regulator circuit 20 of FIG. 2 is shown, in accordance with another embodiment of the disclosure. Example voltage regulator circuit 20D of FIG. 5 is similar to example voltage regulator circuit 20B of FIG. 4, so only differences between them will be described below. Rather than switching the channel connections of the additional devices as in the examples given above, in example voltage regulator circuit 20D, the gate connections of a pair of additional P-channel devices P40 and P42 are set by a pair of switches S2 and S3, respectively. At low output current levels, switch S2 connects the gate terminal of transistor P40 to the gate terminals of transistors P12, P13, so that transistor P40 forms part of the input arm of the output stage current mirror, and switch S3 connects the gate terminal of transistor P41 to power supply voltage V+, turning transistor P41 off. At high output current levels, switch S3 connects the gate terminal of transistor P41 to the gate terminals of transistors P12, P13, so that transistor P41 forms part of the output arm of the output stage current mirror, and switch S2 connects the gate terminal of transistor P40 to power supply voltage V+, turning transistor P40 off. Example voltage regulator circuit 20D is provided as an illustrative example of a technique in which the gates of the one or more additional devices are switched, rather than the channel connections. In practice, a scheme such as that employed in voltage regulator circuit 20C of FIG. 5 may be used to gradually enable/disable the gate connections of transistors P40 and P41, in order to make a gradual change in current mirror ratio,

In summary, this disclosure shows and describes circuits and integrated circuits implementing an amplifier that includes one or more amplifier stages connected in cascade, and a current mirror output stage including an output device and a diode-connected mirror device. A gate of the output device may be coupled to a gate of the mirror device, and the mirror device may be coupled to an output of the one or more amplifier stages to receive the drive signal. The one or more amplifier stages may receive an analog input signal and may generate a drive signal. The current mirror output stage may provide an adjustable ratio by activation of one more additional devices that may be selectively coupled to a mirror arm and an output arm of the current mirror output stage.

In some example embodiments, the one or more amplifier stages may receive an analog feedback signal, and may further include a feedback connection from the output device to provide the analog feedback signal to the one or more amplifier stages. In some example embodiments, the one or more additional devices may be activated according to a measure of an output current provided by the output device to a load. In some example embodiments, the activation of the one or more additional devices may be performed such that, as the output current provided to the load decreases, the current mirroring ratio of the output device to the mirror device is decreased, and as the output current provided to the load increases, the current mirroring ratio of the output device to the mirror device is increased.

In some example embodiments, the one or more additional devices may be activated by a control circuit that switches at least one of the one or more additional devices between the output arm and the mirror arm of the current mirror output stage. In some example embodiments, the one or more additional devices may consist of a single additional device having a gate coupled to the gate of the output device and the gate of the mirror device. In some example embodiments, the control circuit may include a first transistor that couples the single additional device in parallel with the mirror device according to a first control signal, and a second transistor that couples the single additional device in parallel with the output device according to a second control signal. In some example embodiments, the amplifier may further include a first control circuit mirror device having a gate coupled to the gate of the output device and the gate of the mirror device, and a bias circuit that sets a turn-on threshold of the first transistor. The bias circuit may be coupled to the control circuit mirror device to sink a first current provided from the control circuit mirror device. The amplifier may further include a control circuit current mirror coupled to the control circuit mirror device to sink a second current provided from the control circuit mirror device. In some example embodiments, a mirror arm of the control circuit current mirror may be coupled to the output device, so that as a voltage of the output of the current mirror output stage increases, the second current decreases and the first current increases to turn on the first transistor and turn off the second transistor. In some example embodiments, the amplifier may include a hysteresis circuit for providing a hysteresis band of the switching of the second transistor by injecting a hysteresis current into the mirror arm of the control circuit current mirror.

In some example embodiments, the amplifier may include a second control circuit current mirror having a mirror arm coupled to a second control circuit mirror device having a gate coupled to the gate of the output device and the gate of the mirror device and an output arm coupled to the first control circuit current mirror, so that the control circuit current mirror has a current proportional to an output current of the amplifier. In some example embodiments, the one or more additional devices may include a first additional device coupled to the output arm of the current mirror, a second additional device coupled to the mirror arm of the current mirror, and a control circuit that selectively couples a gate of the first additional device or a gate of the second additional device to the gate of the output device and the gate of the mirror device, so that the first additional device forms part of the output arm of the current mirror or the second additional device forms part of the mirror arm of the current mirror, according to the selection by the control circuit.

While the disclosure has shown and described particular embodiments of the techniques disclosed herein, it will be understood by those skilled in the art that the foregoing and other changes in form, and details may be made therein without departing from the spirit and scope of the disclosure. For example, the techniques shown above may be applied to another circuit or system having an amplifier with a power output stage, such as a motor controller or audio amplifier.

What is claimed is:

1. An amplifier, comprising:
one or more amplifier stages connected in cascade, wherein the one or more amplifier stages receive an analog input signal and generate a drive signal; and
a current mirror output stage, wherein the current mirror output stage includes an output device and a diode-connected mirror device, wherein a gate of the output device is coupled to a gate of the mirror device, wherein the mirror device is coupled to an output of the one or more amplifier stages to receive the drive signal, wherein the current mirror output stage provides an adjustable ratio by activation of one more additional devices that are selectively coupled to a mirror arm and an output arm of the current mirror output stage.

2. The amplifier of claim 1, wherein the one or more amplifier stages further receives an analog feedback signal, and further comprising a feedback connection from the output device to provide the analog feedback signal to the one or more amplifier stages.

3. The amplifier of claim 1, wherein the one or more additional devices are activated according to a measure of an output current provided by the output device to a load.

4. The amplifier of claim 3, wherein the activation of the one or more additional devices is performed such that, as the output current provided to the load decreases, the current mirroring ratio of the output device to the mirror device is decreased, and as the output current provided to the load increases, the current mirroring ratio of the output device to the mirror device is increased.

5. The amplifier of claim 3, wherein the one or more additional devices are activated by a control circuit that switches at least one of the one or more additional devices between the output arm and the mirror arm of the current mirror output stage.

6. The amplifier of claim 5, wherein the one or more additional devices consists of a single additional device having a gate coupled to the gate of the output device and the gate of the mirror device, and wherein the control circuit comprises:
a first transistor that couples the single additional device in parallel with the mirror device according to a first control signal; and
a second transistor that couples the single additional device in parallel with the output device according to a second control signal.

7. The amplifier of claim 6, further comprising:
a first control circuit mirror device having a gate coupled to the gate of the output device and the gate of the mirror device;
a bias circuit that sets a turn-on threshold of the first transistor, wherein the bias circuit is coupled to the control circuit mirror device to sink a first current provided from the control circuit mirror device; and
a control circuit current mirror coupled to the control circuit mirror device to sink a second current provided from the control circuit mirror device, wherein a mirror arm of the control circuit current mirror is coupled to the output device, so that as a voltage of the output of the current mirror output stage increases, the second current decreases and the first current increases to turn on the first transistor and turn off the second transistor.

8. The amplifier of claim 7, further comprising a hysteresis circuit for providing a hysteresis band of the switching of the second transistor by injecting a hysteresis current into the mirror arm of the control circuit current mirror.

9. The amplifier of claim 7, further comprising a second control circuit current mirror having a mirror arm coupled to a second control circuit mirror device having a gate coupled to the gate of the output device and the gate of the mirror device and an output arm coupled to the first control circuit current mirror, whereby the control circuit current mirror has a current proportional to an output current of the amplifier.

10. The amplifier of claim 5, wherein the one or more additional devices comprises:
a first additional device coupled to the output arm of the current mirror;
a second additional device coupled to the mirror arm of the current mirror; and
a control circuit that selectively couples a gate of the first additional device or a gate of the second additional device to the gate of the output device and the gate of the mirror device so that the first additional device forms part of the output arm of the current mirror or the second additional device forms part of the mirror arm of the current mirror, according to the selection by the control circuit.

11. A method of improving power efficiency and stability in an amplifier circuit having a current mirror output stage, the method comprising:
generating a drive signal from one or more amplifier stages connected in cascade, wherein the one or more amplifier stages receive an analog input signal; and
providing a power output from a current mirror output stage including an output device and a diode-connected mirror device, wherein a gate of the output device is coupled to a gate of the mirror device, wherein the mirror device is coupled to an output of the one or more amplifier stages to receive the drive signal; and
adjusting a current mirror ratio of the current mirror output stage by activation of one more additional devices that are selectively coupled to a mirror arm and an output arm of the current mirror output stage, whereby the power efficiency is improved by providing a lower output impedance of the output stage at high current output levels, and whereby stability of the amplifier is improved by increasing a pole frequency of the output stage at lower current output levels.

12. The method of claim 11, further comprising receiving an analog feedback signal at an input of the one or more amplifier stages from a feedback connection provided from the output device.

13. The method of claim 1, wherein adjusting the current mirror ratio is performed by activating the one or more additional devices according to a measure of an output current provided by the output device to a load.

14. The method of claim 13, wherein the activating of the one or more additional devices is performed such that, as the output current provided to the load decreases, the current mirroring ratio of the output device to the mirror device is decreased, and as the output current provided to the load increases, the current mirroring ratio of the output device to the mirror device is increased.

15. The method of claim 13, wherein the one or more additional devices are activated by a control circuit that switches at least one of the one or more additional devices between the output arm and the mirror arm of the current mirror output stage.

16. The method of claim 15, wherein the one or more additional devices consists of a single additional device having a gate coupled to the gate of the output device and the gate of the mirror device, and wherein the control circuit comprises:
a first transistor that couples the single additional device in parallel with the mirror device according to a first control signal; and
a second transistor that couples the single additional device in parallel with the output device according to a second control signal.

17. The method of claim 16, wherein the first control signal and the second control signal are generated by a control circuit including first control circuit mirror device having a gate coupled to the gate of the output device and the gate of the mirror device, a bias circuit that sets a turn-on threshold of the first transistor, wherein the bias circuit is coupled to the control circuit mirror device to sink a first current provided from the control circuit mirror device, and a control circuit current mirror coupled to the control circuit mirror device to sink a second current provided from the control circuit mirror device, wherein a mirror arm of the control circuit current mirror is coupled to the output device, so that as a voltage of the output of the current mirror output stage increases, the second current decreases and the first current increases to turn on the first transistor and turn off the second transistor.

18. The method of claim 17, further comprising providing a hysteresis band of the switching of the second transistor by injecting a hysteresis current into the mirror arm of the control circuit current mirror.

19. The method of claim 17, wherein the control circuit further includes a second control circuit current mirror having a mirror arm coupled to a second control circuit mirror device having a gate coupled to the gate of the output device and the gate of the mirror device and an output arm coupled to the first control circuit current mirror, whereby the control circuit current mirror has a current proportional to an output current of the amplifier.

20. The method of claim 15, wherein the one or more additional devices comprises:
a first additional device coupled to the output arm of the current mirror;
a second additional device coupled to the mirror arm of the current mirror; and
a control circuit that selectively couples a gate of the first additional device or a gate of the second additional device to the gate of the output device and the gate of the mirror device so that the first additional device forms part of the output arm of the current mirror or the second additional device forms part of the mirror arm of the current mirror, according to the selection by the control circuit.
